(19) United States
(12) Patent Application Publication
(10) Pub. No.: US 2020/0194319 A1
(43) Pub. Date: Jun. 18, 2020

(54) BACKSIDE COATING FOR TRANSPARENT SUBSTRATE

(71) Applicant: Applied Materials, Inc., Santa Clara, CA (US)

(72) Inventors: Sage Toko Garrett DOSHAY, Saratoga, CA (US); Rutger MEYER TIMMERMAN THIJSSEN, San Jose, CA (US); Ludovic GODET, Sunnyvale, CA (US); Mingwei ZHU, San Jose, CA (US); Naamah ARGAMAN, San Jose, CA (US); Wayne MCMILLAN, San Jose, CA (US); Siddarth KRISHNAN, Santa Clara, CA (US)

(21) Appl. No.: 16/663,918

(22) Filed: Oct. 25, 2019

Related U.S. Application Data
(60) Provisional application No. 62/780,796, filed on Dec. 17, 2018.

(51) Int. Cl. H01L 21/66; H01L 21/67; H01L 21/02

(52) U.S. Cl. CPC H01L 22/24; H01L 22/12; H01L 21/0217; H01L 21/67288; H01L 21/67253

(57) ABSTRACT

Embodiments described herein relate to semiconductor processing. More specifically, embodiments described herein relate to processing of transparent substrates. A film is deposited on a backside of the transparent substrate. A thickness of the film is determined such that the film reflects particular wavelengths of light and substantially prevents bowing of the substrate. The film provides constructive interference to the particular wavelengths of light.

### CROSS-REFERENCE TO RELATED APPLICATIONS

This application claims benefit of U.S. Provisional Patent Application No. 62/780,796, filed Dec. 17, 2018, the entirety of which is herein incorporated by reference.

### BACKGROUND

### Field

Embodiments of the present disclosure generally relate to processing transparent substrates, and more specifically to films deposited on transparent substrates to increase an opacity and/or reflectivity of the transparent substrate.

### Description of the Related Art

Conventional substrate processing equipment utilizes optical sensors, such as lasers, to identify and align substrates for processing therein. However, optical sensors cannot detect a transparent substrate because light from the optical sensor passes through the transparent substrate. A film may be deposited on the substrate to improve detection of the substrate. However, the film can cause bowing of the substrate which interferes with the optical sensors and can result in damage to damage to devices built on the substrate.

Therefore, what is needed in the art is an improved film for processing substrates.

### SUMMARY

In one embodiment, a method of depositing a film is provided. The method includes obtaining a wavelength of light emitted from a sensor. A refractive index of a material is identified. A target thickness of the material is determined by dividing the wavelength of the light emitted from the sensor by two times the refractive index of the material. The material is deposited on a substrate to form a film having the target thickness.

In another embodiment, a method of depositing a film is provided. The method includes obtaining a wavelength of light emitted from a sensor. A refractive index of a silicon containing material is identified. A target thickness of the material is determined by dividing the wavelength of the light emitted from the sensor by two times the refractive index of the material. The material is deposited on a substrate to form a film having the target thickness.

In one embodiment, an apparatus is provided which includes a transparent substrate having a first side and a second side opposite the first side. A film is deposited on the second side of the substrate. The film has a thickness equivalent to a wavelength of a light emitted from a sensor divided by two times a refractive index of a material of the film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates operations of a method for forming a film on a substrate according to an embodiment of the disclosure.

FIG. 2 illustrates an apparatus according to an embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to semiconductor processing. More specifically, embodiments described herein relate to processing of transparent substrates. A film is deposited on a backside of the transparent substrate. A thickness of the film is determined such that the film reflects particular wavelengths of light and substantially prevents bowing of the substrate. The film provides constructive interference to the particular wavelengths of light.

One or more optical sensors, which emit light of a particular wavelength, are used to detect and align substrates for processing. When a transparent substrate is to be processed, the one or more optical sensors cannot detect a transparent substrate because light from the optical sensor passes through the transparent substrate. Thus, a film is deposited on a backside of the transparent substrate to increase a reflectivity or opacity of the substrate by providing constructive interference of the light from the optical sensors. The backside of the substrate is opposite a side of the substrate where one or more devices are formed.

In one embodiment, the film is deposited on the substrate using a chemical vapor deposition (CVD) process. In another embodiment, the film is deposited on the substrate using a plasma enhanced chemical vapor deposition (PECVD) process. It is contemplated that other processes, such as physical vapor deposition, can be used to deposit the film on the substrate.

In one embodiment, which can be combined with one or more embodiments described above, the film deposited on the substrate is a silicon containing material, such as amorphous silicon or silicon nitride. In one embodiment, which can be combined with one or more embodiments described above, silicon nitride is used to increase a reflectivity of the substrate. In another embodiment, which can be combined with one or more embodiments described above, an amorphous silicon layer is used to increase an opacity of the substrate. In another embodiment, which can be combined with one or more embodiments described above, the film on the backside of the substrate is fabricated from a material other than silicon. Any reflectivity or opacity enhancing material may be used for the film. In some embodiments, which can be combined with one or more embodiments described above, the film is fabricated from a single layer. In other embodiments, the film is fabricated from one or more layers of the same or a different material.

A thickness of the film deposited on the backside of the substrate may be determined based on a wavelength of the light emitted from the sensor. For example, a minimum thickness of the film may be determined by:

$$T = \frac{λ}{2 n}$$

where T is the thickness of the film, λ is a wavelength of light emitted from the sensor, and n is a refractive index of the material of the film. The refractive index, n, is a ratio of a speed of light within the material of the film to a speed of light in a vacuum.

In one embodiment, which can be combined with one or more embodiments described above, a thickness of the film deposited on the backside of the substrate is between about 200 nm and about 500 nm, for example, between about 300 nm and about 450 nm, such as about 350 nm. In one embodiment, which can be combined with one or more embodiments described above, a wavelength of the light emitted from the sensor is between about 300 nm and about 800 nm, for example between about 500 nm and about 700 nm, such as about 650 nm.

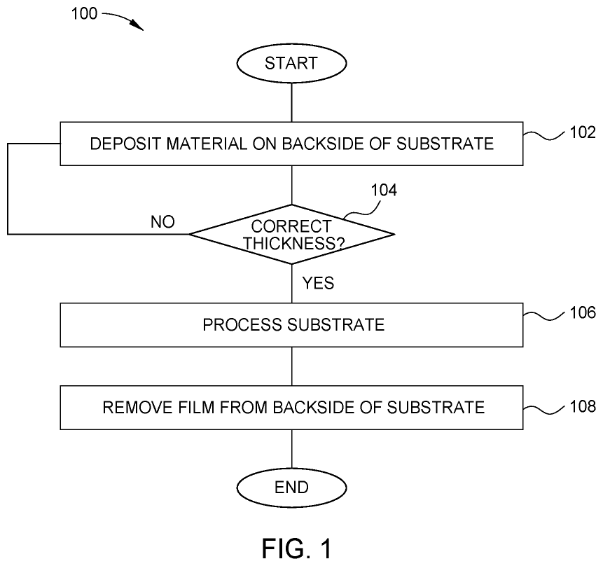

FIG. 1 illustrates operations of a method 100 for forming a film on a substrate according to an embodiment of the disclosure. As shown, the method 100 begins at operation 102 where a material is deposited on a backside of the substrate to form a film. At operation 104, a sensor, such as a laser, is used to determine a thickness of the film deposited on the substrate. If the thickness of the film does not satisfy the equation above, the method 100 proceeds to operation 102 where additional material is deposited on the backside of the substrate to increase the thickness of the film. The film on the backside of the substrate enables constructive interference of light passing through the substrate, thereby increasing a reflectivity of the light. The reflected light from the backside film can be detected by one or more sensors used to align and process the substrate in a process chamber.

Once the thickness of the film satisfies the equation above, the method 100 proceeds to operation 106 where the substrate is processed. In one embodiment, which can be combined with one or more embodiments described above, the substrate is processed by depositing one or more layers on a surface of the substrate opposite the backside of the substrate. The one or more layers may form one or more devices on the substrate.

At operation 108, the film is removed from the backside of the substrate. In one embodiment, which can be combined with one or more embodiments described above, the film is removed using a wet etch technique. Other processes for removing the film from the backside of the substrate include dry etching, laser etching, and others. In one embodiment, which can be combined with one or more embodiments described above, a masking layer may be deposited over the devices formed on the substrate to substantially reduce damage to the devices during the removal operation 108.

In one embodiment, which can be combined with one or more embodiments described above, the film on the backside of the substrate is fabricated from a material different than a material utilized to form the one or more devices. In this way, a selective etch can be utilized to remove the film from the backside while substantially preventing damage to the one or more devices.

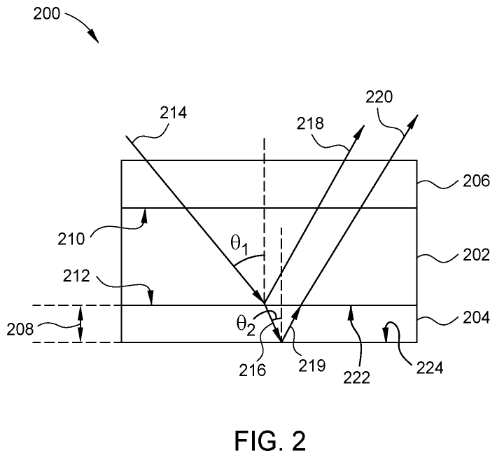

FIG. 2 illustrates an apparatus 200 according to an embodiment of the disclosure. The apparatus 200 includes a transparent substrate 202 including a first surface 210 and a second surface 212 opposite and substantially parallel to the first surface 210. The transparent substrate 202 is fabricated from a transparent material such as glass or fused silica. In one embodiment, which can be combined with one or more embodiments described above, the apparatus 200 is formed according to the method 100 illustrated in FIG. 1.

A backside film 204 is deposited on and adhered to the second surface 212 of the transparent substrate 202. The backside film 204 has a first surface 222 adjacent to the second surface 212 of the substrate 202 and a second surface 224 opposite and substantially parallel to the first surface 222 of the backside film 204. The backside film 204 comprises a silicon containing material, such as amorphous silicon or silicon nitride. A thickness 208 of the backside film 204 corresponds to a refractive index of the material used to form the backside film 204. The thickness 208 also corresponds to a wavelength of light emitted from a sensor used to detect and align the substrate 202. The backside film 204 increases a reflectivity of the transparent substrate 202 while substantially preventing or substantially reducing an amount of bowing of the transparent substrate 202 caused by the backside film 204.

One or more layers 206 are deposited on and adhered to the first surface 210 of the transparent substrate 202. In one embodiment, which can be combined with one or more embodiments described above, the one or more layers 206 are deposited on the transparent substrate 202 utilizing, for example, a CVD process, a PECVD process, or a physical vapor deposition (PVD) process. Other deposition processes may be utilized.

After the one or more layers 206 are deposited on the transparent substrate 202, the backside film 204 is removed utilizing a selective etch process, such as a wet etch. The selective etch process substantially removes the backside film 204 while minimizing damage to the transparent substrate 202 and the one or more layers 206.

In operation, light is projected from a sensor toward the substrate 202 along a path 214. While the path 214 is shown at an angle θ₁ from a plane that is substantially normal to the first surface 222 of the film 204, it is contemplated that the path 214 is substantially perpendicular to the first surface 222. That is, θ₁ may be substantially zero. When the light intersects the first surface 222 of the film 204, a first portion of the light is reflected along a first reflective path 218. A second portion of the light is refracted at the first surface 222 of the film 204 and travels through the film 204 along a path 216. The path 216 is an angle θ₂ from a plane that is substantially normal to the second surface 224 of the film 204, which is different than θ₁. The second portion of the light reflects off of the second surface 224 of the film 204 and travels along a path 219. When the second portion of the light intersects the first surface 222 of the film 204, the second portion of the light is refracted to travel along a second reflective path 220. The second reflective path 220 is substantially parallel to the first reflective path 218 of the first portion of the light. In one embodiment, which can be combined with one or more embodiments described above, only a portion of the second portion of light reflects off of the second surface of the second surface 224 of the film 204.

The film 204 provides constructive interference of the light from the sensor when a length of the second reflective path 220 is an integer multiple of the wavelength λ of the light emitted from the sensor. In one embodiment, which can be combined with one or more embodiments described above, the length of the second reflective path 220 is determined by

L=2n cos(θ₂)

where L is the length of the second reflective path 220 and n is the refractive index of the material of the backside film 204.

Embodiments described herein provide a backside coating for transparent substrates. Advantageously, the backside coating on the substrate enables use of one or more sensors to detect and align the substrate in a process chamber. A thickness of the backside coating enables a particular wavelength of light emitted from the one or more sensors to be reflected from the coating while substantially preventing bowing of the substrate.

While the foregoing is directed to embodiments of the present disclosure, other and further embodiments of the disclosure may be devised without departing from the basic scope thereof, and the scope thereof is determined by the claims that follow.

What is claimed is:

1. A method of depositing a film, comprising:
obtaining a wavelength of light emitted from a sensor;
identifying a refractive index of a material;
determining a target thickness of the material by dividing the wavelength of the light emitted from the sensor by two times the refractive index of the material; and
depositing the material on a substrate to form a film having the target thickness.

2. The method of claim 1, wherein the wavelength of the light emitted from the sensor is between about 500 nm and about 700 nm.

3. The method of claim 2, wherein the wavelength of the light emitted from the sensor is about 650 nm.

4. The method of claim 1, further comprising:
depositing one or more layers on a side of the substrate opposite the film.

5. The method of claim 1, wherein the target thickness is between about 300 nm and about 450 nm.

6. The method of claim 1, wherein the film causes constructive interference of the light emitted from the sensor.

7. The method of claim 1, further comprising:
performing a selective etch to remove the film from the substrate.

8. The method of claim 1, wherein a refractive index is a ratio of a speed of light traveling through the material to a speed of light traveling through a vacuum.

9. A method of depositing a film, comprising:
obtaining a wavelength of light emitted from a sensor;
identifying a refractive index of a silicon containing material;
determining a target thickness of the material by dividing the wavelength of the light emitted from the sensor by two times the refractive index of the material; and
depositing the material on a substrate to form a film having the target thickness.

10. The method of claim 9, wherein the silicon containing material comprises silicon nitride.

11. The method of claim 9, wherein the wavelength of the light emitted from the sensor is between about 500 nm and about 700 nm.

12. The method of claim 9, wherein the wavelength of the light emitted from the sensor is about 650 nm.

13. The method of claim 9, further comprising:
depositing one or more layers on a side of the substrate opposite the film.

14. The method of claim 9, wherein the target thickness is between about 300 nm and about 450 nm.

15. The method of claim 9, further comprising:
performing a selective etch to remove the film from the substrate.

16. The method of claim 9, wherein the film increases at least one of a reflectivity and an opacity of the substrate.

17. An apparatus, comprising:
a transparent substrate having a first side and a second side opposite the first side; and
a film deposited on the second side of the substrate, the film having a thickness equivalent to a wavelength of light emitted from a sensor divided by two times a refractive index of a material of the film.

18. The apparatus of claim 17, further comprising:
one or more layers deposited on the first side of the substrate.

19. The apparatus of claim 17, wherein the film is a reflective film which reflects light of the wavelength of the sensor.

20. The apparatus of claim 17, wherein the film comprises silicon nitride.
